(19) United States
(12) Patent Application Publication
(10) Pub. No.: US 2008/0149978 A1
(43) Pub. Date: Jun. 26, 2008

(54) Memory device and method of fabricating a memory device

(76) Inventor: Till Schloesser, Dresden (DE)

Correspondence Address: SLATER & MATSIL LLP, 17950 PRESTON ROAD, SUITE 1000, DALLAS, TX, 75252, US

(21) Appl. No.: 11/645,124

(22) Filed: Dec. 21, 2006

(51) Int. Cl. H01L 27/108; H01L 21/768

(52) U.S. Cl. 257/296; 438/640; 257/E27.088; 257/E21.578

(57) ABSTRACT

A memory device, comprising a semiconductor substrate with at least one storage cell, the storage cell comprising a storage element and a selection transistor, wherein the memory device further comprises a storage element contact assigned to the storage cell, the storage element contact extending from the selection transistor to the storage element along an axis that at least partially runs obliquely with respect to a direction perpendicular to the substrate surface.

### TECHNICAL FIELD

This invention generally relates to a memory device comprising at least one storage cell, the storage cell including a storage element for storing electrical charges and a selection transistor that controls charging and discharging of the storage element.

### BACKGROUND

A plurality of different memory cell types using this basic layout is known. Examples of such memory devices include DRAM (dynamic random access memory), FRAM (ferroelectric random access memory) and PCRAM (phase change random access memory) chips. The storage element (a capacitor in the case of a DRAM device) of a storage cell is electrically connected to an active area of the selection transistor.

Memory devices such as DRAM or FRAM comprise a plurality of storage cells that are arranged along parallel columns. Depending on the layout of the memory device, active areas of the storage cells have to be arranged non-equally spaced along a storage cell column (i.e., the distance between neighboring active areas is not constant along a column). This requires the storage elements of the storage cells to be arranged non-uniformly also, which in turn results in a complicated lithographic process necessary for the fabrication of the storage elements.

### SUMMARY OF THE INVENTION

The invention refers to a memory device, comprising a semiconductor substrate with at least one storage cell, the storage cell comprising a storage element and a selection transistor; a storage element contact assigned to the storage cell, the storage element contact extending from the selection transistor to the storage element along an axis that at least partially runs obliquely with respect to a direction perpendicular to the substrate surface.

Furthermore, the invention refers to methods of fabricating a memory device. The fabrication methods comprise providing a substrate with a plurality of active areas formed along a plurality of parallel columns, each active area being a component of a selection transistor and comprising a storage element contact portion, the storage element contact portions of the plurality of active areas being disposed in pairs, wherein the distance between the contact portions of a contact portion pair is smaller than the distance between two neighboring contact portion pairs, the distance being measured along a direction parallel to active area columns.

The invention allows storage elements of a memory device to be arranged in a regular manner, e.g., in a checker board layout.

### BRIEF DESCRIPTION OF THE DRAWINGS

Embodiments and advantages of the invention become apparent upon reading of the detailed description of the invention, and the appended claims provided below, and upon reference to the drawings.

FIG. 1 schematically shows a typical contact structure of a memory device;

FIG. 2 schematically shows storage capacitors in a checker board layout;

FIG. 3 schematically shows a capacitor contact structure of a memory device according to an embodiment of the invention;

FIGS. 4a to 4f schematically show fabrication steps according to an embodiment of a fabrication method of the invention;

FIGS. 5a to 5f schematically show fabrication steps of a second fabrication method of the invention; and

FIGS. 6a and 6b show fabrication steps according to a third fabrication method of the invention.

### DETAILED DESCRIPTION OF ILLUSTRATIVE EMBODIMENTS

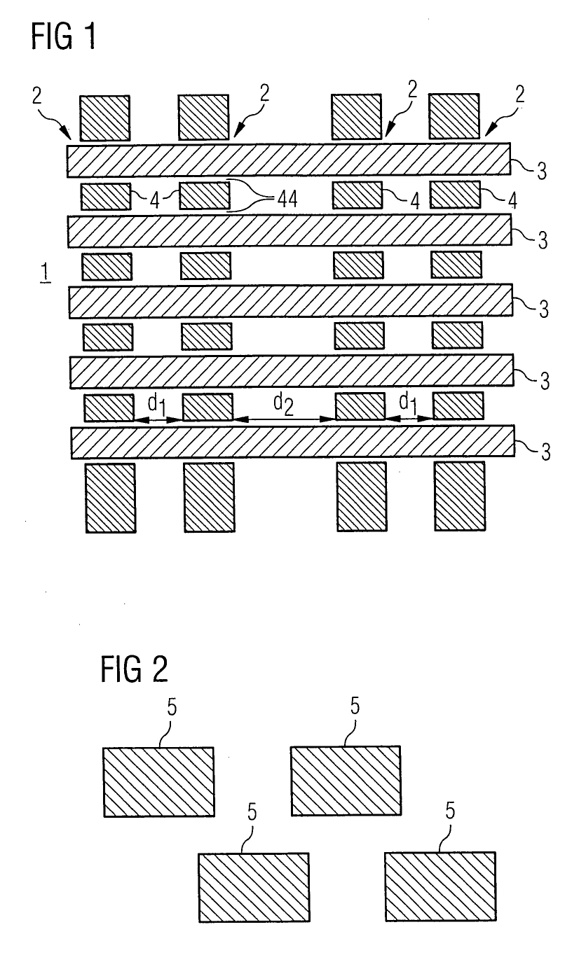

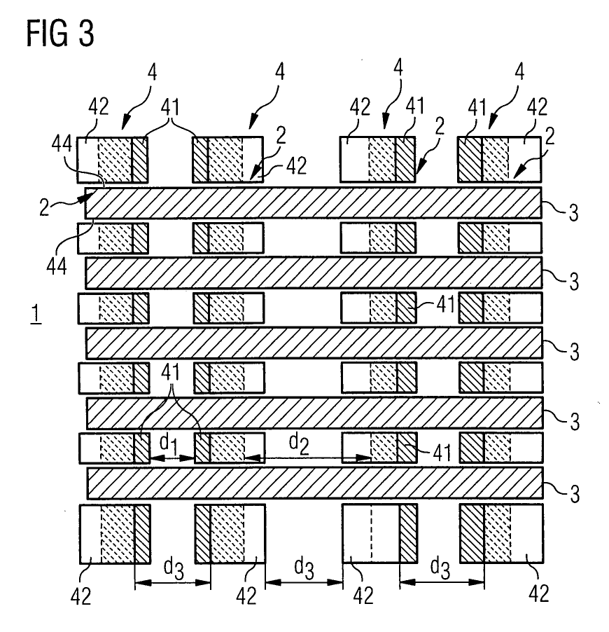

FIG. 1 depicts a section of a typical contact layout of a memory device, such as a DRAM. The structure is shown as a top view (as in FIGS. 2 and 3).

On a semiconductor substrate 1 a plurality of parallel bit lines 3 are disposed, wherein the bit lines 3 electrically connect storage cells 2 that are arranged in (imaginary) columns running parallel to the bit lines 3. Each of the storage cells 2 comprises a storage element in the form of a storage capacitor (not shown) and a selection transistor which is electrically contacted to the capacitor. The selection transistors are formed within a surface area of the semiconductor substrate 1, i.e., below the bit lines 3.

The selection transistors of the plurality of storage cells each comprise an active area with a capacitor contact region (storage element contact portion) connected to the capacitor of the storage cell, a gate region connected to a gate electrode (not shown) and a further region that is connected to one of the bit lines 3. The region of a selection transistor that is connected to a bit line represents a source/drain area of the selection transistor, whereas the capacitor contact region of a selection transistor conversely represents a drain/source region. Whether a region is to be construed a source region or a drain region depends on the electrical potential applied to the respective region, i.e., whether an electrical charge is to be stored to the assigned capacitor or to be read from the capacitor. The principle of DRAM storage cells, however, is well known, such that it is not described in greater detail.

The contact regions of the selection transistors each are electrically connected to a capacitor via capacitor contacts 4. The capacitor contacts 4 are disposed between the bit lines 3 and extend in a straight fashion perpendicular to the surface of the semiconductor substrate 1. The capacitors (not shown) are connected to the (upper) endings of the capacitor contact facing away from the substrate 1. In order to avoid short circuits, the capacitor contacts 4 are isolated from the bit lines 3 by an isolating material 44 such as silicon oxide.

As is shown in FIG. 1, the capacitor contacts 4 are non-equally spaced with respect to a direction parallel to the bit lines 3 (horizontal direction in FIG. 1) due to the fact that the underlying contact portions of the selection transistors have to be arranged in a non-uniform manner to meet the layout requirements of the memory device. According to FIG. 1 the distance d₁, d₂ between two neighboring capacitor contacts 4 of one storage cell column (along one of the bit lines 3) alternate such that d₂ is greater than d₁, more particularly d₁ is 1 F as d₂ is 3F. Here, the distances d₁, d₂ are measured between opposite sides (facing each other) of two neighboring capacitor contact structures.

FIG. 2 shows a checker board layout of a plurality of storage capacitors 5, wherein the capacitors 5 each belong to one storage cell of a memory device. However, arranging the capacitors in a checker board layout is problematic with the capacitor contacts as shown in FIG. 1. One problem is that, in a checkerboard layout, the overlay between a capacitor and the assigned capacitor contact is small resulting in a high contact resistance. Another major problem is that, due to the small overlay, variations of the overlay can hardly be tolerated such that lithography requirements have to be very strict.

FIG. 3 depicts a section of a memory device structure according an embodiment of the invention. As in the structure of FIG. 1, a plurality of parallel bit lines 3 is disposed connected to a plurality of storage cells 2 arranged on a semiconductor substrate 1. The bit lines 3 are connected to active regions of a selection transistor (not shown) contained in each storage cell 2.

The selection transistors as illustrated in FIG. 1 each comprise a capacitor contact region that is connected to a capacitor (not shown) via capacitor contacts 4 extending between two neighboring bit lines 3. In contrast to the straight capacitor contacts of FIG. 1, the capacitor contacts 4 of FIG. 3 (i.e., an axis of the contacts) run obliquely with respect to a direction perpendicular to the substrate surface. Each capacitor contact 4 comprises a first end (side) 41 that is in contact with the substrate surface (i.e., with a contact region of a selection transistor such as a drain/source region of the selection transistor). The capacitor contacts 4 further comprise a second end (side) 42 that is located opposite to the first end 41 and connects to the capacitor (not shown) of a storage cell 2.

As can be further seen from the top view in FIG. 3, the second side 42 of each capacitor contact 4 is laterally displaced with respect to the first side 41 of the contact due to the fact that each capacitor contact extends along an axis that runs obliquely. Furthermore, the first sides 41 of the capacitor contacts 4 of one storage cell column (running parallel the bit lines 3) are non-equally spaced with respect to a direction along the bit lines 3.

More particularly, two neighboring first sides are spaced with alternating distances d₁, d₂, wherein the distance d₁ is 1F and distance d₂ is 3F (as in FIG. 1). As the first sides 41 are non-equally spaced, the second sides 42 of the capacitor contacts 4 of one storage cell column are essentially equally spaced, i.e., a distance d₃ between the second sides 42 of two neighboring capacitor contacts 4 is essentially constant. The uniform arrangement of the second sides 42 of the capacitor contacts 4 permits a checkerboard capacitor layout (FIG. 2) be arranged on top of the structure, wherein the capacitors are connected to the (equally spaced) second sides 42 of the capacitor contacts 4.

More particular, the oblique capacitor contacts permit to arrange the capacitors in a checkerboard layout with a larger overlay, thereby reducing the contact resistance. Further, the enlarged overlay allows a more stable fabrication process and less restrict lithography requirements during the fabrication of the capacitors.

Although the embodiment of FIG. 3 comprises capacitor contacts that are equally spaced at their (second) sides (facing towards the capacitors), capacitor contacts that are spaced alternating with respect to theses contact sides lie within the scope of the invention. It is important that the capacitor contacts run obliquely with respect to a direction perpendicular to the substrate surface, but the contacts do not necessarily have to be arranged with a constant distance with respect to their endings facing the capacitors. Also, the slope of the oblique capacitor contacts does not have to be the same for all contacts. Capacitor contacts with different slopes also lie within the scope of this invention (as do capacitor contacts with differently tapered side walls).

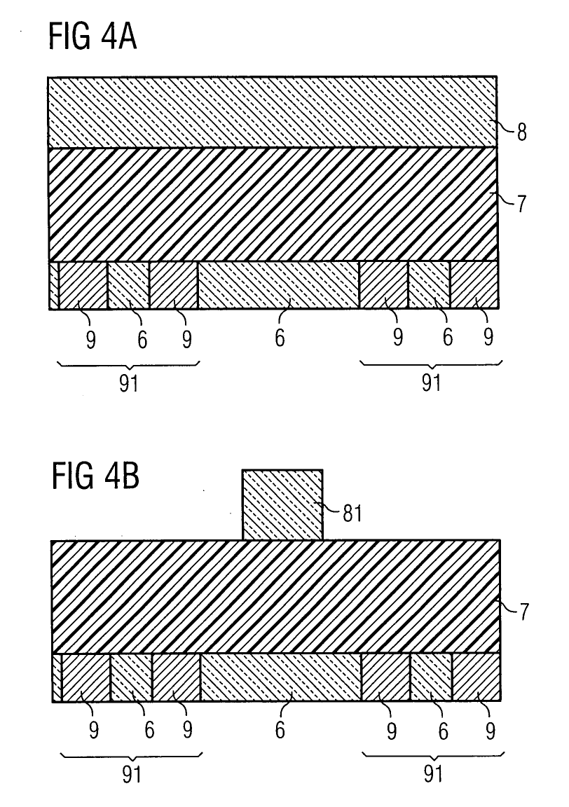

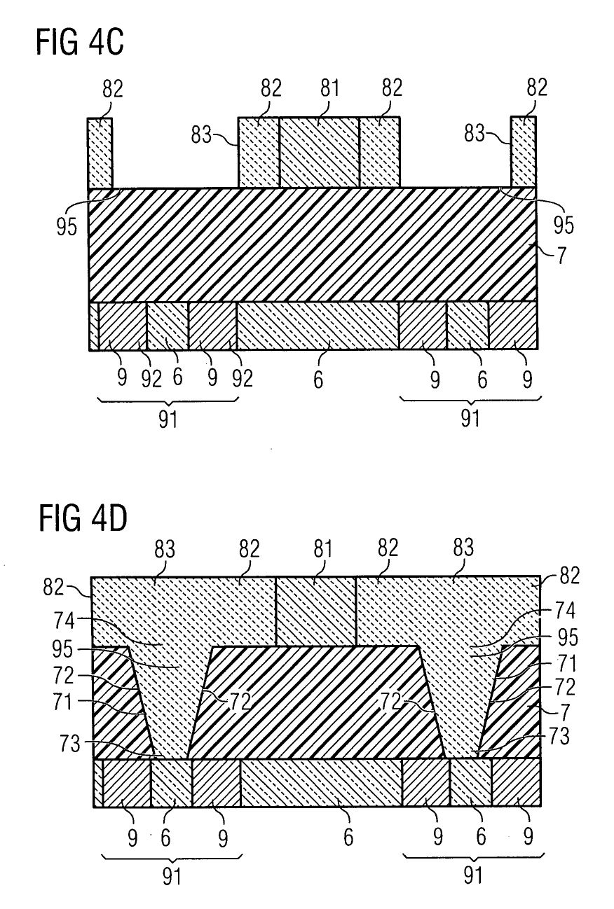

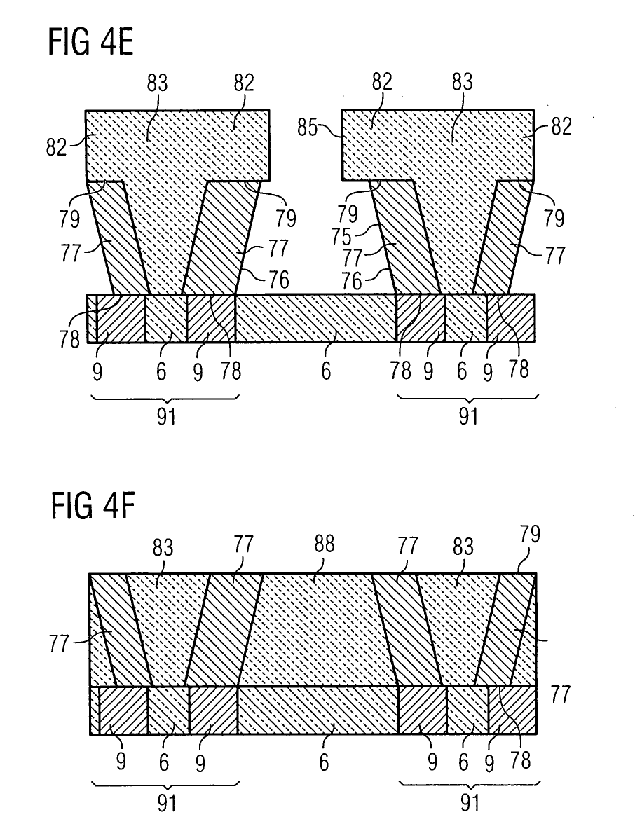

FIGS. 4a to 4f illustrate a fabrication process for oblique capacitor contacts of a memory device according to the invention. Referring to FIG. 4a, storage element contact portions in the form of conductive landing pads 9 are arranged on a semiconductor substrate (not shown), wherein each of the landing pads is connected to an active area of a selection transistor (not shown). The landing pads 9 extend in a straight manner perpendicular to the substrate surface and connect to a capacitor contact portion of a selection transistor of a storage cell (not shown), wherein each of the landing pads 9 belongs to a different storage cell. The landing pads 9 are non-equally spaced (as are the capacitor contact portions of the selection transistors), wherein the space between them alternates with distances d₁, d₂, d₁ being greater than d₂. Two neighboring landing pads 9 separated by the smaller distance d₁ are regarded to form a landing pad pair 91, although the landing pads belong to different storage cells.

The landing pads 9 are formed of poly silicon and are electrically isolated from each other by silicon oxide 6 disposed between them. On top of the landing pads 9 a conductive layer 7 of poly silicon is deposited, the poly silicon layer 7 in turn being covered by a silicon nitride hard mask 8.

According to FIG. 4b, the nitride hard mask 8 is structured by applying a resist photo mask (i.e., a lithography step) followed by an etch step (either dry or wet etching). The hard mask then comprises structures 81 which are located on the conductive layer 7 and are aligned to a region in the middle between two neighboring landing pad pairs 91. Although only one structure 81 of the nitride hard mask is shown in FIG. 4b, a plurality of such structures is formed in the hard mask layer (corresponding to the total number of landing pad pairs), each of the hard mask structures being located in the region between two neighboring landing pad pairs.

Next (referring to FIG. 4c), silicon oxide is deposited on top of the structure such that spacer structures 82 are formed on the level of the nitride hard mask structures 81 and adjacent to the hard mask structures 81. Spacer structures 82 adjacent to different hard mask structures 81 are separated from each other by openings 83 in order to not cover the conductive layer 7 in a region 95 between the landing pads 9 of each of the landing pad pairs 91. The width of the openings 83 is chosen to also uncover a region of the conductive layer that partially extends over opposite side portions 92 of the landing pads 9 of a landing pad pair 91.

As shown in FIG. 4d, first openings 71 are formed in the poly silicon conductive layer 7 in a region 95 between the landing pads 9 of the landing pad pairs 91. The openings 71 each have a bottom 73 uncovering a region between two landing pads 9 and each comprise a top portion 74 located on the level of the interface between the conductive layer 7 and the hard mask layer 8. A dry etch step is applied to form the first openings 71 in the poly silicon layer 7 with tapered side walls 72. The side walls 72 are tapered in such a manner that the openings 71 widen from the bottom 73 to the top portion 74 (i.e., the openings 71 are defined by positively tapered side walls). The first openings 71 as well as the openings 83 between two neighboring oxide spacers 82 are filled with silicon oxide segments 83.

In a further step (referring to FIG. 4e), the remaining hard mask structure 81 on top of the poly silicon layer 7 is removed (applying a dry or a wet etch step) to uncover a portion of the poly silicon layer 7 in a region between two neighboring landing pad pairs 91 (opening 85 between two oxide spacers 82, 83). Subsequently, poly silicon is removed from layer 7 in a region below the opening 85 using dry or wet etching for fabricating an opening 75 in the conductive layer 7 with negatively tapered side walls 76.

As a result, the conductive layer 7 consists of obliquely extending capacitor contacts 77 that with a first side 78 are connected to an assigned landing pad 9. The opposite (second) side 79 of each contact 77 is to be connected to a capacitor (not shown) of a storage cell. For this, the oxide layer 82, 83 on top of the contact layer (now consisting of contacts 77) has to be removed down to the contacts 77. This is done by chemical mechanical polishing (CMP), generating oblique contacts 77 with accessible second sides 79, wherein the contacts 77 are electrically isolated from each other by silicon oxide material 88 that is located between them.

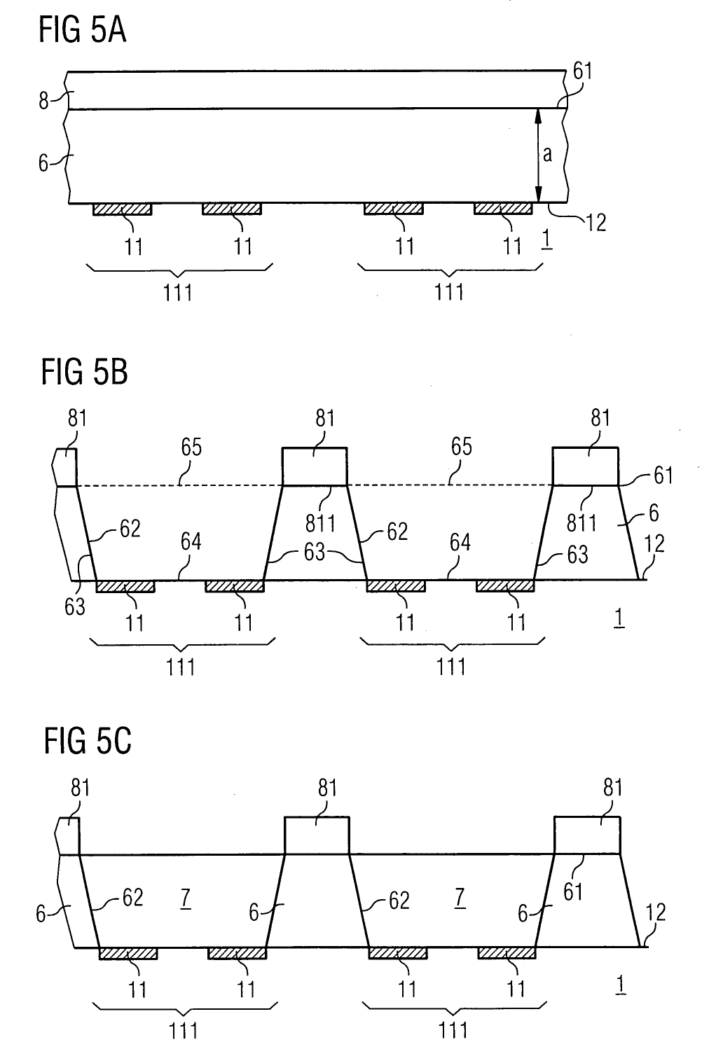

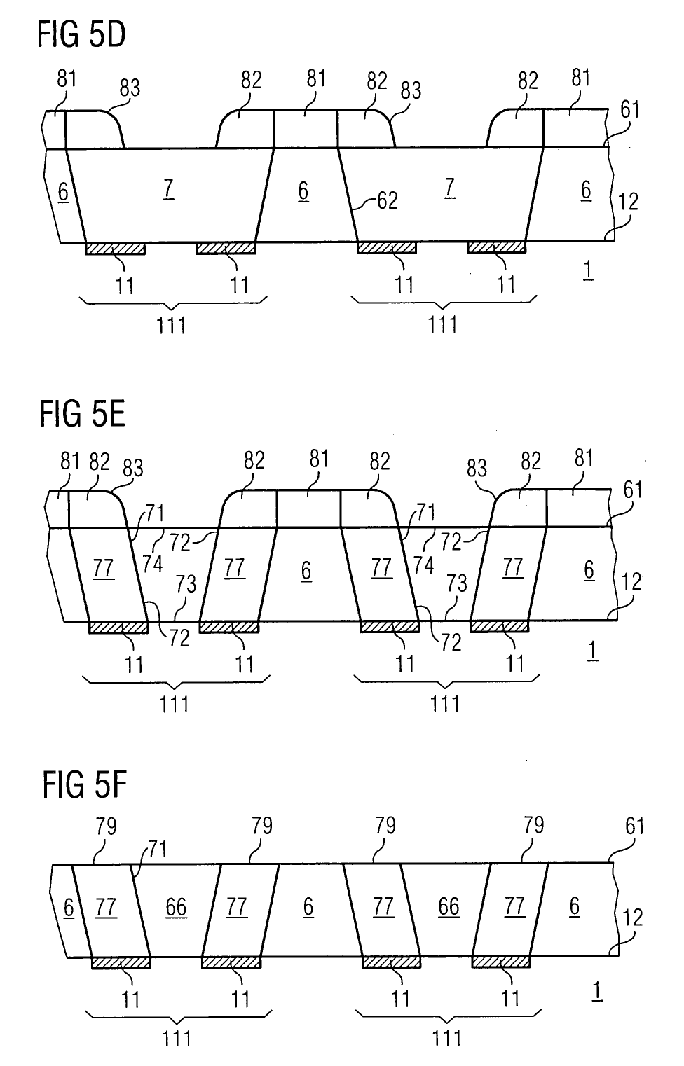

FIGS. 5a to 5f illustrate another fabrication process for oblique capacitor contacts of a memory device according to the invention. Referring to FIG. 5a, a semiconductor substrate 1 comprises active areas (capacitor contact portions) 11, wherein each active area 11 is assigned to a selection transistor (not shown) of a storage cell. The active areas 11 are formed in a surface region 12 (AA level) of the semiconductor substrate 1. The active areas 11 are disposed non-equally spaced such that they are regarded to be arranged in pairs 111, although they are assigned to different storage cells. As an alternative, the active areas 11 can be connected to electrically conductive landing pads as in the embodiment according to FIGS. 4a-4f.

A silicon oxide layer 6 is formed on top of the semiconductor substrate 1, the oxide layer 6 in turn being covered by a layer 8 of silicon nitride. The thickness a of the silicon oxide layer 6 is chosen such that the upper surface 61 (at the interface with the nitride layer 8) of the layer 6 approximately matches the height (above the AA level) of bit lines (that are not present yet, but will be disposed within the further fabrication process of the memory device).

According to FIG. 5b, the hard mask layer 8 is structured using a (lithographically structures) resist mask on top of the layer and a dry etch process to obtain hard mask structures 81 located on the silicon oxide layer 6. More particularly, the hard mask structures 81 are generated in a region 811 between two neighboring active area pairs 111 (more precisely, in a region between the neighboring active areas of two different neighboring active area pairs). At the same time, the hard mask 8 is structured to uncover regions where bit lines of the memory device are to be fabricated (using the same line photo mask as for producing the hard mask structures 81).

Further, applying a further etch step, openings 62 are produced in the oxide layer 6 uncovering the active area pairs 11, the openings 62 having (positively) tapered side walls 63. The openings 62 are thus formed widening from a bottom 64 (on the AA-level) to a top portion 65 (located at the interface between the oxide layer 6 and the hard mask layer 8, i.e., the bit line level 61).

Referring to FIG. 5c, the openings 62 are filled with a conductive material in the form of poly silicon portions 7. This is done by depositing poly silicon over the complete structure followed by a planarization step (e.g., dry etching or CMP) with stop on the hard mask layer 8 (i.e., on the hard mask structures 81). In a further step, the poly silicon is recessed to the upper surface of the oxide layer 6 (i.e., to the bit line height of the memory device).

In a further step (referring to FIG. 5d), spacer structures 82 are deposited on the poly silicon portions 7 and adjacent to the hard mask structures 81. The spacer structures 82 are formed of silicon oxide and are arranged with a distance to each other in order to create openings 83 in a region between two active areas 11 of an active area pair 111. Further (FIG. 5e), openings 71 are etched within the poly silicon portions 7, the openings 71 having positively tapered side walls 72, i.e., the openings 71 widen from a bottom side 73 (uncovering a region between the active areas 11 of the active area pairs 111) to a top side 74 (at the interface to the hard mask structures 81). As a result, obliquely running (capacitor) contacts 77 are formed between the outer sidewalls of the poly silicon portions 7 and the tapered side walls 72 of the openings 71.

In a stripping step, the silicon nitride hard mask structures 81 are removed (e.g., by wet or dry etching) and silicon oxide is deposited to fill the opening 71 between two oblique contacts 77. For this, the deposited silicon oxide is planarized (CMP or dry etching) with stop on the upper sides 79 of the contacts 77 (that are located with a height above the substrate surface 12 corresponding to the height of the bit lines of the memory device).

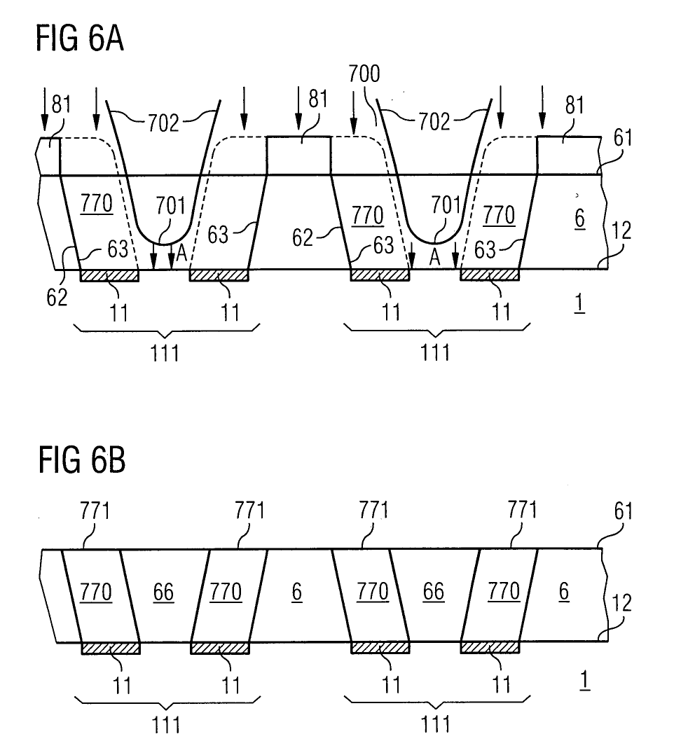

FIGS. 6a and 6b refer to another fabrication method according to the invention. First, a semiconductor substrate 1 comprising active areas 11 arranged in pairs 111 is covered with a silicon oxide layer 6. On the oxide layer 6 in turn a silicon nitride hard mask layer 8 is formed (corresponding to FIG. 5a). The layers 6, 8 are then structured as described with respect to FIGS. 5a and 5b. The resulting structure is shown in FIG. 6a.

This structure is subsequently covered with a thin poly silicon layer 700. Since the poly silicon layer 700 is thin, it does not extend in a planar fashion, but extends along the existing structures. That is, the poly silicon layer 700 has bumps in the region of the hard mask structures 81 and recesses 701 in the region of the openings 62 in the silicon oxide layer 6. The recesses 701 comprise side walls 702 that cover side walls 63 of the openings 62.

The poly silicon layer 700 is etched back such that the recesses 701 reach the substrate surface (i.e., the AA level 12) uncovering a region between the active areas 11 of the active area pairs 111. The etch back process is indicated in FIG. 6a by arrows A. Etching back the poly silicon layer 700 results in generating (capacitor) contacts 770 extending obliquely from the active areas 11 along the side walls 63 of the openings 62 in the oxide layer 6. The opposite side walls (corresponding to the side walls 702 of the recesses 701 in the poly silicon layer 700 before the etch back step) of the contacts 770 are indicated by dashed lines.

Referring to FIG. 6b, after stripping the hard mask structures 81 (e.g., by wet or dry etching) the openings between the capacitor contacts 770 are filled with silicon oxide portions 66. This is done by depositing silicon oxide over the structure of FIG. 6a and planarizing the oxide with stop on the upper side 771 of the contacts 770. The contacts each are thus connected to an active area with a first side and are to be connected to capacitors with a second (upper) side 771. The upper side 771 is located at approximately the height 61 of bit lines of the memory device.

An advantage of the fabrication methods set forth above is that a simpler lithography can be used during the fabrication of the capacitor contacts due to the fact that the capacitors are spaced with a single period, only. Additionally, the distance (the so-called “pitch”, if the distance is measured from the middle of neighboring structures) between the inventive neighboring hard mask structures 81 (that are used to structure the conductive layer 7 below) is greater than the distance between hard mask structures used for fabricating the known straight capacitor contacts (since the fabrication of the known structure comprises generating a hard mask structure between all of the active areas).

In the case of a 6F2 layout, the pitch between the active areas is 1F and 3F, respectively. For fabricating the known device, equally spaced hard mask structures with a distance of 2F are needed. The hard mask structures 81 as used in the inventive fabrication method are located in the bigger (3F) gap between two neighboring active areas, only, and thus have a distance of 4F. In other words, the invention permits doubling of the pitch.

The foregoing detailed description discloses only the preferred embodiments of the invention, modifications of the above-disclosed device and method that fall within the scope of the invention will be apparent to those of ordinary skill in the art. For example, the invention is not restricted to a particular kind of storage cells. Although the embodiments describe above refer to a DRAM cell, the invention can be applied to all types of storage cells comprising a storage element and a selection device. Further, alternative materials can be employed during the fabrication of the device. For instance, a different conductive material can be used instead of poly silicon and different insulating material such as silicon nitride can be used instead of silicon oxide.

What is claimed is:

1. A memory device, comprising
a semiconductor substrate with at least one storage cell, the storage cell comprising a storage element and a selection transistor; and
a storage element contact assigned to the storage cell, the storage element contact extending from the selection transistor to the storage element along an axis that at least partially runs obliquely with respect to a direction perpendicular to the substrate surface.

2. The memory device according to claim 1, wherein
a plurality of storage cells are arranged in a plurality of parallel columns,
each storage cell comprises a selection transistor, a storage element and an assigned storage element contact,
the selection transistor of each storage cell comprises a storage element contact portion which is electrically connected to the storage element of the storage cell via the storage element contact, and
the storage element contact portions of the plurality of storage cells are arranged parallel to the storage cell columns.

3. The memory device according to claim 2, wherein the storage element contact portions are essentially non-equally spaced with respect to a direction parallel to the storage cell columns.

4. The memory device according to claim 3, wherein
each storage element contact comprises a first and a second side, wherein the first side is connected to the storage element contact portion of the selection transistor of one of the storage cells,
the second side is connected to the storage element of the storage cell,
the storage element contacts assigned to the plurality of storage cells are arranged essentially non-equally spaced with respect to their first sides and essentially equally spaced with respect to their second sides, the space between the storage element contacts being measured along a direction parallel to the storage cell columns.

5. The memory device according to claim 4, wherein the first side of each storage element contact faces towards the substrate surface, whereas the second side is turned away from the substrate surface.

6. The memory device according to claim 4, wherein the storage element contact portions are spaced alternating with a first distance and second distance with respect to a direction parallel to the storage cell rows, the second distance being greater than the first distance.

7. The memory device according to claim 6, wherein the first distance is 1F and the second distance is 3F.

8. The memory device according to claim 4, further comprising a plurality of conductive lines electrically connecting the selection transistors of the storage cells, the conductive lines extending parallel to the storage cell columns.

9. The memory device according to claim 8, wherein the conductive lines correspond to bit lines of the memory device.

10. The memory device according to claim 9, wherein each selection transistor in addition to the storage element contact portion comprises a bit line contact portion which is connected to a bit line of the memory device via a bit line contact.

11. The memory device according to claim 10, wherein the storage element contact portion is connected to or represents a source/drain region of the selection transistor, whereas the bit line contact portion complementary is connected to or represents a drain/source region of the selection transistor.

12. The memory device according to claim 4, further comprising a bit line, wherein the second side of each storage element contact and a side of the bit line facing away from the substrate are located with approximately the same distance to the substrate surface.

13. The memory device according to claim 2, wherein the storage element contact portion comprises a metal or a poly silicon layer on the substrate or a doped region in the substrate.

14. The memory device according to claim 1, wherein the storage element contacts are separated from each other by isolation material.

15. The memory device according to claim 1, wherein the storage element contacts comprise poly silicon or a metal and the isolation material comprises silicon oxide or silicon nitride.

16. The memory device according to claim 1, wherein the storage element is a capacitor.

17. The memory device according to claim 1, wherein the memory device is formed as a DRAM device with a 6F2 layout.

18. Method of fabricating a memory device comprising the steps of:
providing a substrate with a plurality of active areas formed along a plurality of parallel columns, each active area being a component of a selection transistor and comprising a storage element contact portion, the storage element contact portions of the plurality of active areas being disposed in pairs, wherein the distance between the contact portions of a contact portion pair is smaller than the distance between two neighboring contact portion pairs, the distance being measured along a direction parallel to active area columns;
fabricating a plurality of storage element contacts, each storage element contact being electrically connected to one of the storage element contact portions and extending along an axis which at least partially runs obliquely with respect to a direction perpendicular to the substrate surface, wherein fabricating the storage element contacts comprises:
forming a conductive layer on the substrate;
forming a plurality of first openings with tapered sidewalls in the conductive layer, the first openings each being aligned to a region between the contact portions of each contact portion pair and widening from bottom to top;
forming a plurality of second openings with tapered sidewalls in the conductive layer, the second openings each being aligned to a region between neighboring contact portions of different contact portion pairs and narrowing from bottom to top; and
filling the first and second openings in the conductive layer with isolation material.

19. The method according to claim 18, wherein forming the first and second openings in the contact layer comprises:
forming a hard mask layer on the conductive layer and patterning the hard mask layer to form hard mask structures aligned to a region between the contact portion pairs;
forming spacer structures on the conductive layer and adjacent to the hard mask structures such that the spacer structures do not cover the conductive layer between the contact portions of each contact portion pair;
performing an etching step in order to form the first openings in the conductive layer;
filling the first openings with isolation material;
performing an etching step in order to remove the hard mask structures; and
performing an etching step in order to form the second openings in the conductive layer.

20. The method according to claim 19, further comprising removing the isolation material on top of the conductive layer after forming the second openings.

21. The method according to claim 20, wherein each active area further comprises a bit line contact portion and the method further comprises fabricating a plurality of bit line contacts, each bit line contact being connected to one of the bit line contact portions.

22. The method according to claim 21, wherein the plurality of the bit line contacts and the plurality of the storage element contacts are fabricated simultaneously.

23. The method according to claim 22, further comprising fabricating a plurality of parallel bit lines, each bit line being connected to a plurality of the bit line contacts.

24. Method of fabricating a memory device comprising the steps of:
providing a substrate with a plurality of active areas formed along a plurality of parallel columns, each active area being a component of a selection transistor and comprising a storage element contact portion, the storage element contact portions of the plurality of active areas being disposed in pairs, wherein the distance between the contact portions of a contact portion pair is smaller than the distance between two neighboring contact portion pairs, the distance being measured along a direction parallel to active area columns;
fabricating a plurality of storage element contacts, each storage element contact being electrically connected to one of the storage element contact portions and extending along an axis which at least partially runs obliquely with respect to a direction perpendicular to the substrate surface, wherein fabricating the storage element contacts comprises:
forming an isolation layer on the substrate;
forming a hard mask layer on the isolation layer and patterning the hard mask layer to form hard mask structures aligned to a region between the contact portion pairs;
performing an etching step in order to form a plurality of openings with tapered sidewalls in the isolation layer, each opening being aligned to a region between the hard mask structures, each opening further uncovering one contact portion pair and widening from bottom to top;
filling the openings with conductive material;
forming openings with tapered sidewalls in the conductive material, the openings each being aligned to a region between the contact portions of each contact portion pair and widening from bottom to top; and
filling the openings in the conductive material with isolation material.

25. The method according to claim 24, wherein forming the openings in the conductive material comprises:
forming spacer structures on the conductive material and adjacent to the hard mask structures such that the spacer structures do not cover the conductive layer between the contact portions of each contact portion pair; and
performing an etching step in order to form the openings in the conductive material.

26. The method according to claim 25, wherein the hard mask structures and the spacer structures are removed after the filling the openings in the conductive material.

27. The method according to claim 26, wherein the isolation layer is planarized.

28. The method according to claim 27, wherein filling the openings in the isolation layer comprises a deposition of poly silicon and a planarization of the poly silicon with stop on the hard mask layer;

29. Method of fabricating a memory device comprising the steps of:
providing a substrate with a plurality of active areas formed along a plurality of parallel columns, each active area being a component of a selection transistor and comprising a storage element contact portion, the storage element contact portions of the plurality of active areas being disposed in pairs, wherein the distance between the contact portions of a contact portion pair is smaller than the distance between two neighboring contact portion pairs, the distance being measured along a direction parallel to active area columns;
fabricating a plurality of storage element contacts, each storage element contact being electrically connected to one of the storage element contact portions and extending along an axis which at least partially runs obliquely with respect to a direction perpendicular to the substrate surface, wherein fabricating the storage element contacts comprises:
forming an isolation layer on the substrate;
forming a hard mask layer on the isolation layer and patterning the hard mask layer to form hard mask structures aligned to a region between the contact portion pairs;
performing an etching step in order to form a plurality of openings in the isolation layer with tapered sidewalls between the hard mask structures, each opening uncovering one contact portion pair and widening from the substrate to the top of the isolation layer;
forming a conductive layer covering the bottom and the sidewalls of the openings; and
etching back the conductive layer to uncover the bottom of opening between the contact portions of the contact portion pairs, wherein the sidewalls of the openings remain covered by the conductive layer.

30. The method according to claim 29, wherein the hard mask structures are removed after the etching back of the conductive layer.

31. The method according to claim 30, wherein the opening is filled with isolation material after the etching back of the conductive layer.
